(19) United States
(12) Patent Application Publication
(10) Pub. No.: US 2020/0185477 A1
(43) Pub. Date: Jun. 11, 2020

(54) DISPLAY PANEL, METHOD MANUFACTURING SAME AND DISPLAY MODULE

(71) Applicant: Wuhan China Star Optoelectronics Semiconductor Display Technology Co., Ltd., Wuhan (CN)

(72) Inventor: Chongchong XIA, Wuhan (CN)

(73) Assignee: Wuhan China Star Optoelectronics Semiconductor Display Technology Co., Ltd., Wuhan (CN)

(21) Appl. No.: 16/319,496

(22) PCT Filed: Jan. 7, 2019
(86) PCT No.: PCT/CN2019/070678

§ 371 Date: Jan. 22, 2019

(30) Foreign Application Priority Data
Dec. 6, 2018 (CN) 201811485629.4

(51) Int. Cl. H01L 27/32; H01L 51/52; H01L 51/56

(52) U.S. Cl. CPC H01L 27/3258; H01L 51/5253; H01L 27/1248; H01L 27/3248; H01L 51/56; H01L 27/3246

(57) ABSTRACT

A display panel, a method for manufacturing same, and a display module are provided, including a substrate, a thin film transistor layer on the substrate, a planarization layer on the thin film transistor layer, a light emitting element layer on the planarization layer; and an encapsulation layer on the light emitting element layer, wherein the planarization layer includes a first protrusion, and an orthographic projection of the light emitting element layer projected on the first protrusion is located within the first protrusion.

### FIELD OF INVENTION

The present application relates to a technical field in displays, and particularly to a display panel, a method for manufacturing same, and a display module.

### BACKGROUND OF DISCLOSURE

An organic light-emitting diode (OLED) display has many advantages, such as light weight, thin thickness, active lighting, fast responses, wide viewing angles, a wide color gamut, high brightness, and low power consumption. The OLED display has gradually become the third generation display technology subsequent to liquid crystal displays.

In an evaporation process of a light emitting layer of an existing OLED display panel, due to irregular openings of a metal mask and a gap between a substrate and the metal mask, internal shadows are formed during coating, resulting in incomplete evaporation of light emitting units, making pixels in the display panel out of color, and reducing the yield of the display panels.

### SUMMARY OF INVENTION

The present disclosure provides a display panel, a method manufacturing same, and a display module, so as to solve the technical problem of pixels being out of color in existing display panels.

In order to solve the aforementioned problems, the technical solution provided by the present disclosure is as follows:

A display panel is provided in the present disclosure, including:

a substrate;

a thin film transistor layer disposed on the substrate;

a planarization layer disposed on the thin film transistor layer;

a light emitting element layer disposed on the planarization layer; and

an encapsulation layer disposed on the light emitting element layer;

wherein the planarization layer includes a first protrusion, and an orthographic projection of the light emitting element layer projected on the first protrusion is located within the first protrusion.

In the display panel of the present disclosure, the display panel further includes a pixel defining layer; wherein a sum of thicknesses of the first protrusion and an anode layer of the light emitting element layer is smaller than a thickness of the pixel defining layer.

In the display panel of the present disclosure, the display panel further includes a first via hole, wherein an anode layer of the light emitting element layer is electrically connected to a source drain layer of the thin film transistor layer through the first via hole.

In the display panel of the present disclosure, the first via hole penetrates through the first protrusion, and penetrates through the planarization layer between the first protrusion and the source drain layer.

In the display panel of the present disclosure, the first via hole penetrates through the planarization layer.

In the display panel of the present disclosure, the planarization layer is formed by a multi-segment mask, the multi-segment mask includes a first region, a second region, and a third region, light transmittances of the first region, the second region, and the third region are sequentially increased, the first region corresponds to the first protrusion of the planarization layer, the third region corresponds to the first via hole in the planarization layer, and the second region corresponds to a region of the planarization layer other than the first protrusion and the first via hole.

In the display panel of the present disclosure, the light transmittances of the first region, the second region, and the third region are sequentially increased.

A method for manufacturing a display panel is provided in the present disclosure, including:

a step S10 of providing a substrate and forming a thin film transistor layer on the substrate;

a step S20 of forming a first film layer on the thin film transistor layer, and using a first photomask to form the first film layer into a planarization layer including a first protrusion;

a step S30 of forming a light emitting element layer on the planarization layer; and

a step S40 of forming an encapsulation layer on the light emitting element layer;

wherein an orthographic projection of the light emitting element layer projected on the first protrusion is located within the first protrusion.

In the manufacturing method of the present disclosure, before the step S30, the manufacturing method further comprises following steps of:

forming a pixel defining layer on the planarization layer;

wherein a sum of thicknesses of the first protrusion and an anode layer of the light emitting element layer is smaller than a thickness of the pixel defining layer.

In the manufacturing method of the present disclosure, the step S20 comprises:

a step S201 of forming the first film layer on the thin film transistor layer; and

a step S202 of using a multi-segment mask to pattern the first film layer into the planarization layer including the first protrusion and a first via hole;

wherein an anode layer of the light emitting element layer is electrically connected to a source drain layer of the thin film transistor layer through the first via hole.

In the manufacturing method of the present disclosure, the first via hole penetrates through the first protrusion, and penetrates through the planarization layer between the first protrusion and the source drain layer.

In the manufacturing method of the present disclosure, the multi-segment mask includes a first region, a second region, and a third region, light transmittances of the first region, the second region, and the third region are sequentially increased, the first region corresponds to the first protrusion of the planarization layer, the third region corresponds to the first via hole in the planarization layer, and the second region corresponds to a region of the planarization layer other than the first protrusion and the first via hole.

In the manufacturing method of the present disclosure, the light transmittances of the first region, the second region, and the third region are sequentially increased.

A display module is provided in the present disclosure, including a display panel, a polarizing layer and a cover layer on the display panel, wherein the display panel includes:

a substrate;

a thin film transistor layer disposed on the substrate;

a planarization layer disposed on the thin film transistor layer;

a light emitting element layer disposed on the planarization layer; and

an encapsulation layer disposed on the light emitting element layer;

wherein the planarization layer includes a first protrusion, and an orthographic projection of the light emitting element layer projected on the first protrusion is located within the first protrusion.

In the display module of the present disclosure, the display module further includes a pixel defining layer; wherein a sum of thicknesses of the first protrusion and an anode layer of the light emitting element layer is smaller than a thickness of the pixel defining layer.

In the display module of the present disclosure, the display module further includes a first via hole, wherein an anode layer of the light emitting element layer is electrically connected to a source drain layer of the thin film transistor layer through the first via hole.

In the display module of the present disclosure, the first via hole penetrates through the first protrusion, and penetrates through the planarization layer between the first protrusion and the source drain layer.

In the display module of the present disclosure, the first via hole penetrates through the planarization layer.

In the display module of the present disclosure, the planarization layer is formed by a multi-segment mask, the multi-segment mask includes a first region, a second region, and a third region, light transmittances of the first region, the second region, and the third region are sequentially increased, the first region corresponds to the first protrusion of the planarization layer, the third region corresponds to the first via hole in the planarization layer, and the second region corresponds to a region of the planarization layer other than the first protrusion and the first via hole.

In the display module of the present disclosure, the light transmittances of the first region, the second region, and the third region are sequentially increased.

Beneficial Effects:

In the present disclosure, vertical space between the pixel defining layer and the anode layer is reduced by adding the first protrusion on the planarization layer, thereby reducing inner shadow region generated when the light emitting layer is formed by using the metal mask, reducing the risk of pixel out of color in the display panel, and increasing the yield of the display panel.

### BRIEF DESCRIPTION OF DRAWINGS

In order to more clearly illustrate the embodiments of the present invention or the technical solutions in prior arts, the following briefly introduces the accompanying drawings used in the embodiments. Obviously, the drawings in the following description merely show some of the embodiments of the present invention. As regards one of ordinary skill in the art, other drawings can be obtained in accordance with these accompanying drawings without making creative efforts.

FIG. 1 is a structural diagram of film layers of a display panel of the present disclosure.

FIG. 2 is a flowchart of a method for manufacturing a display panel of the present disclosure.

FIG. 3A-FIG. 3H are process diagrams of a method for manufacturing a display panel of the present disclosure.

### DETAILED DESCRIPTION OF PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure.

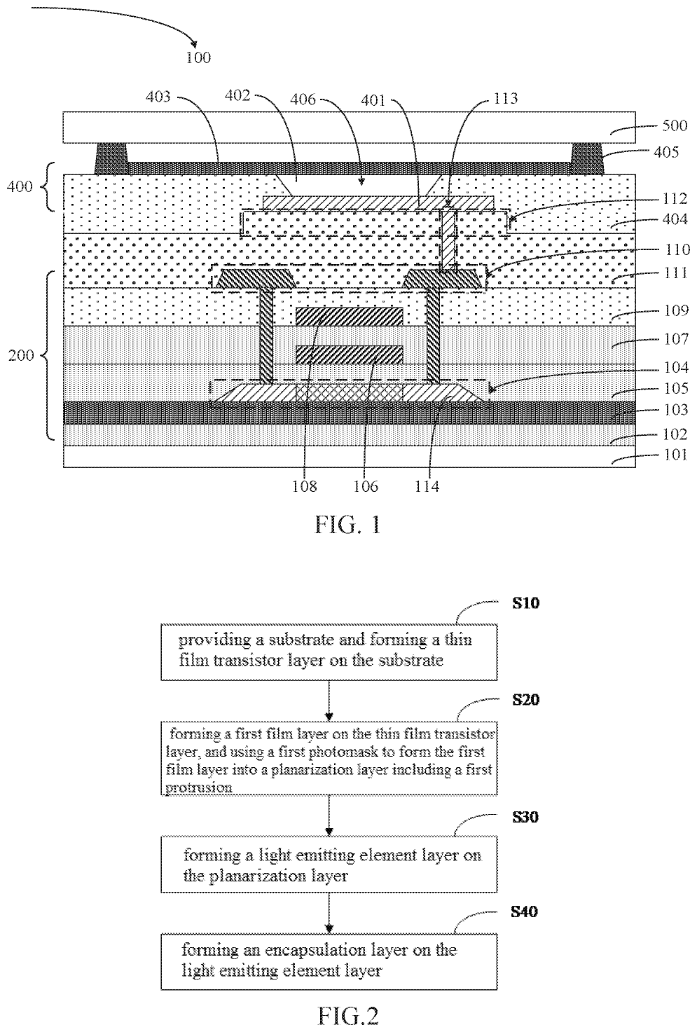

Refer to FIG. 1, which is a structural diagram of film layers of a display panel of the present disclosure.

The display panel 100 includes components as follows:

A substrate 101: material of the substrate 101 may be one of a glass substrate, a quartz substrate, a resin substrate, and the like. In an embodiment, the substrate 101 may also be a flexible substrate. Material of the flexible substrate may be polyimide (PI).

A thin film transistor layer 200 disposed on the substrate:

The thin film transistor layer 200 includes an etch barrier layer type structure, a backchannel etching type structure, or a top gate thin film transistor type structure, etc. The specific details are not limited. For instance, the thin film transistor layer 200 of the top gate thin film transistor type structure includes a barrier layer 102, a buffer layer 103, an active layer 104, a first gate insulating layer 105, a gate 106, a second gate insulating layer 107, a second metal layer 108, an interlayer insulating layer 109, and a source drain layer 110.

In an embodiment, the substrate 101 is a flexible substrate. Material of the flexible substrate may include polyimide.

The barrier layer 102 is formed on the substrate 101. In an embodiment, material of the barrier layer 102 includes silicon oxide.

The buffer layer 103 is formed on the barrier layer 102, and is mainly used for buffering the pressure between lamellar structures, and may also have a function of blocking water and oxygen.

In an embodiment, material of the buffer layer 103 includes one or more compositions of silicon nitride or silicon oxide.

The active layer 104 is formed on the buffer layer 103, and the active layer 104 includes an ion-doped doping region 114.

The first gate insulating layer 105 is formed on the active layer 104. The first gate insulating layer 105 covers the active layer 104, and the first gate insulating layer 105 is mainly used for isolating the active layer 104 from a metal layer located above the active layer 104.

The gate 106 is formed on a first insulating layer 304. Metal material of the gate 106 may be generally a metal, such as molybdenum, aluminum, an aluminum-nickel alloy, a molybdenum-tungsten alloy, chromium, or copper, or may be a combination of the aforementioned metal materials.

In an embodiment, metal material of the gate 106 may be molybdenum.

The second gate insulating layer 107 is formed on the gate 106. The second gate insulating layer 107 is mainly used for isolating the gate 106 from the second metal layer 108.

In an embodiment, material of the first gate insulating layer 105 and the second gate insulating layer 107 may be silicon nitride, silicon oxide, silicon oxynitride, or the like.

The second metal layer 108 is formed on the second gate insulating layer 107. In an embodiment, metal material of the second metal layer 108 is the same as the gate 106.

The interlayer insulating layer 109 is formed on the second metal layer 108, and the interlayer insulating layer 109 covers the second metal layer 108, and is mainly used for isolating the second metal layer 108 from the source drain layer 110.

In an embodiment, material of the interlayer insulating layer 109 may be the same as those of the first gate insulating layer 105 and the second gate insulating layer 107.

The source drain layer 110 is formed on the interlayer insulating layer 109. Metal material of the source drain layer 110 may be a metal, such as molybdenum, aluminum, aluminum-nickel alloy, molybdenum-tungsten alloy, chromium, copper or titanium aluminum alloy, or may be a combination of the aforementioned metal materials.

The source drain layer 110 is electrically connected to the doping region 114 through a via hole. In an embodiment, metal material of the source drain layer 110 is a titanium aluminum alloy.

A planarization layer 111 disposed on the thin film transistor layer.

In an embodiment, the planarization layer 111 may be formed of an organic film layer to increase flexibility of the display panel 100.

The planarization layer 111 includes a first protrusion 112 and a first via hole 113.

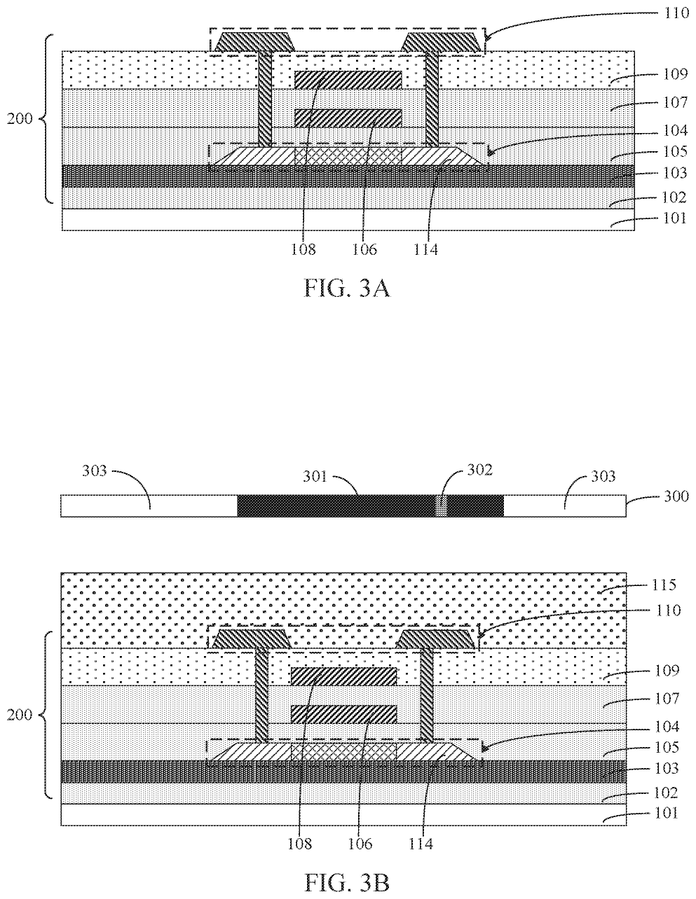

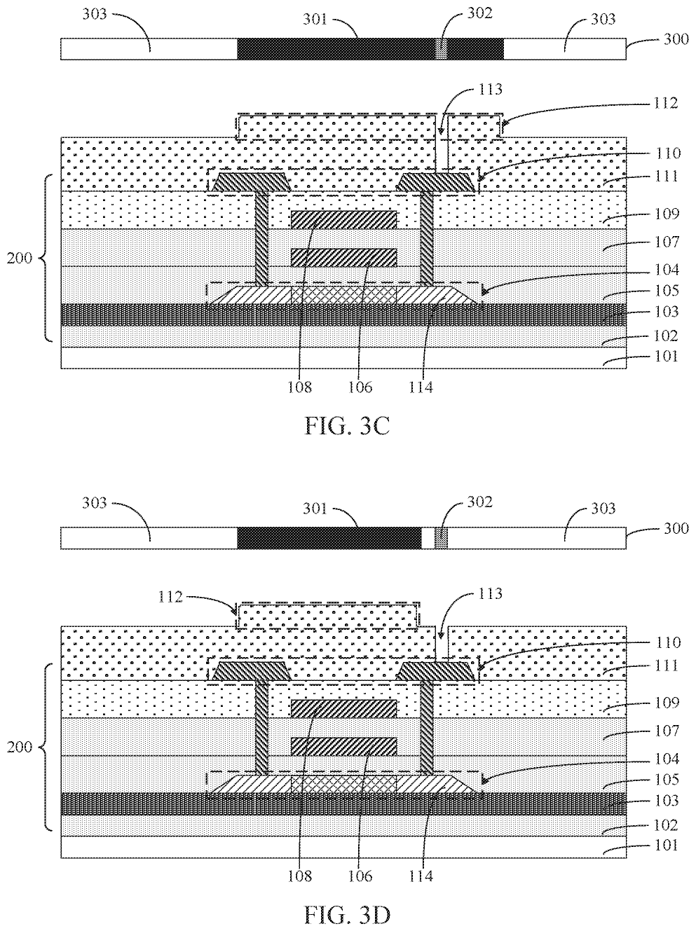

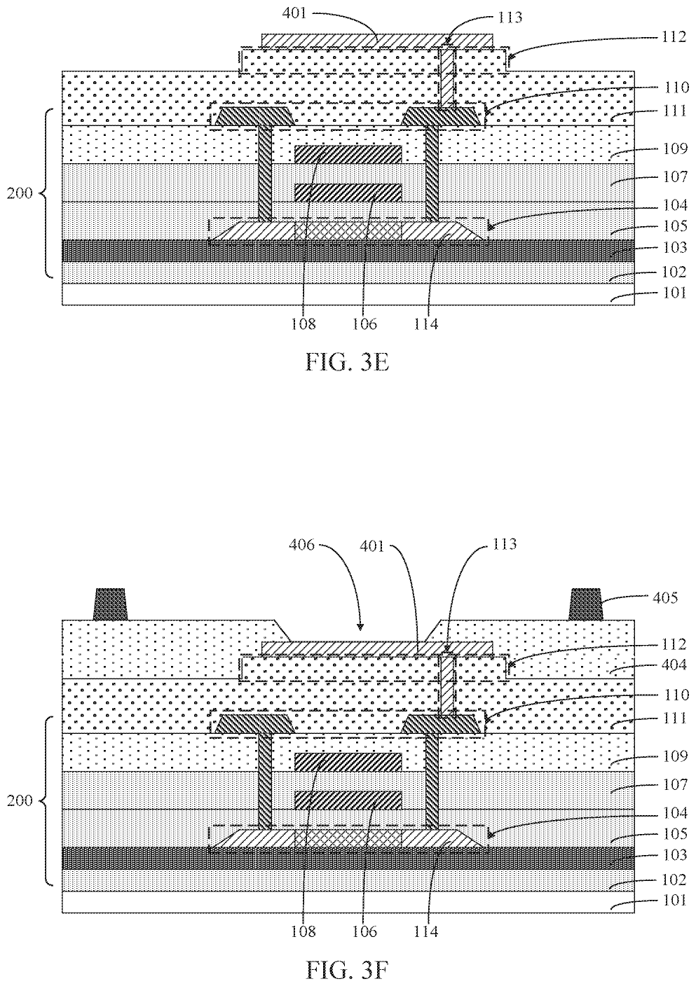

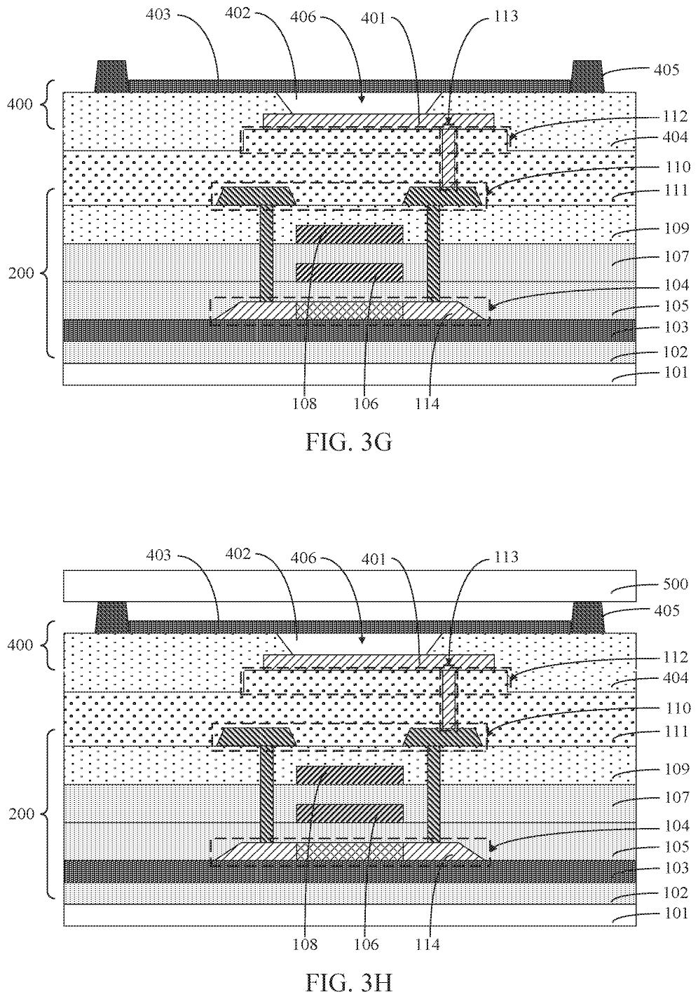

Refer to FIG. 3C. In an embodiment, the planarization layer 111 is formed by a multi-segment mask 300, and the multi-segment mask 300 includes a first region 301, a second region 302, and a third region 303, light transmittances of which are sequentially increased. The first region 301 corresponds to the first protrusion 112 of the planarization layer 111, the third region 303 corresponds to the first via hole 113 in the planarization layer 111, and the second region 302 corresponds to a region of the planarization layer 111 other than the first protrusion 112 and the first via hole 113.

In an embodiment, the first region 301 has a light transmission of 0%. The light transmittance of the third region 303 is 100%. The light transmittance of the second region 302 is between the first region 301 and the third region 303, and the specific value may be set according to actual conditions.

In an embodiment, the first via hole 113 penetrates through the first protrusion 112, and penetrates through the planarization layer 111 between the first protrusion 112 and the source drain layer 110.

Refer to FIG. 3D. In an embodiment, the first via hole 113 is located in a side of the first protrusion 112. In this embodiment, the first via hole 113 may only penetrate through the planarization layer 111.

A light emitting element layer 400 includes an anode layer 401, a light emitting layer 402, and a cathode layer 403 formed on the planarization layer 111.

In an embodiment, the light emitting element is a top emission type organic light emitting diode (OLED). The anode layer 401 is a non-transparent metal electrode.

In an embodiment, an orthographic projection of the anode layer 401 projected on the first protrusion 112 is located within the first protrusion 112. The anode layer 401 is electrically connected to the source drain layer 210 of the thin film transistor 200 through the first via hole 113.

Refer to FIG. 1. The display panel 100 further includes a pixel defining layer 404 and a supporting layer 405 on the anode layer 401.

The pixel defining layer 404 includes a first opening 406 that is located on the anode layer 401. A sum of thicknesses of the first protrusion 112 and the anode layer 401 of the light emitting element layer 400 is smaller than a thickness of the pixel defining layer 404.

In an embodiment, material of the pixel defining layer 404 and the supporting layer 405 may be photosensitive photoresist material.

The light emitting layer 402 is divided into a plurality of light emitting units by the pixel defining layer 404, and each of the light emitting units corresponds to an anode unit in the anode layer 401.

The cathode layer 403 covers the light emitting layer 402 and the pixel defining layer 404 located on the planarization layer 111.

In an embodiment, the cathode layer 403 is transparent material.

In an embodiment, material of the cathode layer 403 may be selected from at least one of indium tin oxide (ITO), indium zinc oxide (IZO), zinc oxide (ZnO), indium oxide (In₂O₃), indium gallium oxide (IGO) or zinc aluminum oxide (AZO).

An encapsulation layer 500 disposed on the light emitting element layer 400:

In an embodiment, the encapsulation layer 500 may be a rigid glass cover.

In the present disclosure, vertical space between the pixel defining layer and the anode layer is reduced by adding the first protrusion on the planarization layer, thereby reducing inner shadow region generated when the light emitting layer is formed by using the metal mask, reducing the risk of pixel out of color in the display panel, and increasing the yield of the display panel.

Refer to FIG. 2, which is a flowchart of a method for manufacturing a display panel of the present disclosure.

Refer to FIG. 3A-FIG. 3H, which are process diagrams of a method for manufacturing a display panel of the present disclosure.

A method for manufacturing a display panel is provided in the present disclosure, including the following steps:

A step S10 of providing a substrate 101 and forming a thin film transistor layer 200 on the substrate 101:

Refer to FIG. 3A. Material of the substrate 101 may be one of a glass substrate, a quartz substrate, a resin substrate, and the like. In an embodiment, the substrate 101 may also be a flexible substrate. Material of the flexible substrate may be polyimide (PI).

The thin film transistor layer 200 includes an etch barrier layer type structure, a backchannel etching type structure, or a top gate thin film transistor type structure, etc. The specific details are not limited. For instance, the thin film transistor layer 200 of the top gate thin film transistor type structure includes a barrier layer 102, a buffer layer 103, an active layer 104, a first gate insulating layer 105, a gate 106, a second gate insulating layer 107, a second metal layer 108, an interlayer insulating layer 109, and a source drain layer 110.

In an embodiment, the substrate 101 is a flexible substrate. Material of the flexible substrate may include polyimide.

The barrier layer 102 is formed on the substrate 101. In an embodiment, material of the barrier layer 102 includes silicon oxide.

The buffer layer 103 is formed on the barrier layer 102, and is mainly used for buffering the pressure between lamellar structures, and may also have a function of blocking water and oxygen.

In an embodiment, material of the buffer layer 103 includes one or more compositions of silicon nitride or silicon oxide.

The active layer 104 is formed on the buffer layer 103, and the active layer 104 includes an ion-doped doping region 114.

The first gate insulating layer 105 is formed on the active layer 104. The first gate insulating layer 105 covers the active layer 104, and the first gate insulating layer 105 is mainly used for isolating the active layer 104 from a metal layer located above the active layer 104.

The gate 106 is formed on a first insulating layer 304. Metal material of the gate 106 may be generally a metal, such as molybdenum, aluminum, an aluminum-nickel alloy, a molybdenum-tungsten alloy, chromium, or copper, or may be a combination of the aforementioned metal materials.

In an embodiment, metal material of the gate 106 may be molybdenum.

The second gate insulating layer 107 is formed on the gate 106. The second gate insulating layer 107 is mainly used for isolating the gate 106 from the second metal layer 108.

In an embodiment, material of the first gate insulating layer 105 and the second gate insulating layer 107 may be silicon nitride, silicon oxide, silicon oxynitride, or the like.

The second metal layer 108 is formed on the second gate insulating layer 107. In an embodiment, metal material of the second metal layer 108 is the same as the gate 106.

The interlayer insulating layer 109 is formed on the second metal layer 108, and the interlayer insulating layer 109 covers the second metal layer 108, and is mainly used for isolating the second metal layer 108 from the source drain layer 110.

In an embodiment, material of the interlayer insulating layer 109 may be the same as those of the first gate insulating layer 105 and the second gate insulating layer 107.

The source drain layer 110 is formed on the interlayer insulating layer 109. Metal material of the source drain layer 110 may be a metal, such as molybdenum, aluminum, aluminum-nickel alloy, molybdenum-tungsten alloy, chromium, copper or titanium aluminum alloy, or may be a combination of the aforementioned metal materials.

The source drain layer 110 is electrically connected to the doping region 114 through a via hole. In an embodiment, metal material of the source drain layer 110 is a titanium aluminum alloy.

A step S20 of forming a first film layer 115 on the thin film transistor layer 200, and using a first photomask to form the first film layer 115 into a planarization layer 111 including a first protrusion 112:

The step S20 specifically includes following steps:

A step S201 of forming the first film layer 115 on the thin film transistor layer 200.

Refer to FIG. 3B. The first film layer 115 may be an organic film layer to increase flexibility of the display panel.

A step S202 of using a multi-segment mask 300 to pattern the first film layer 115 into the planarization layer 111 including the first protrusion 112 and a first via hole 113.

Refer to FIG. 3C. In the step, the first film layer 115 is formed into a planarization layer 111 including the first protrusion 112 and the first via hole 113 by using the multi-segment mask 300.

In an embodiment, the first via hole 113 penetrates through the first protrusion 112, and penetrates through the planarization layer 111 between the first protrusion 112 and the source drain layer 110.

Refer to FIG. 3D. In an embodiment, the first via hole 113 is located in a side of the first protrusion 112. In this embodiment, the first via hole 113 may only penetrate through the planarization layer 111.

The multi-segment mask 300 includes a first region 301, a second region 302, and a third region 303, light transmittances of which are sequentially increased. The first region 301 corresponds to the first protrusion 112 of the planarization layer 111, the third region 303 corresponds to the first via hole 113 in the planarization layer 111, and the second region 302 corresponds to a region of the planarization layer 111 other than the first protrusion 112 and the first via hole 113.

In an embodiment, the first region 301 has a light transmittance of 0%. The light transmittance of the third region 303 is 100%. The light transmittance of the second region 302 is between the first region 301 and the third region 303, and the specific value may be set according to actual conditions.

A step S30 of forming a light emitting element layer 400 on the planarization layer 111:

The light emitting element layer 400 includes an anode layer 401, a light emitting layer 402, and a cathode layer 403 formed on the planarization layer 111.

The step S30 specifically includes:

A step S301 of forming the anode layer 401 on the planarization layer 111:

Refer to FIG. 3E. The anode layer 401 is mainly used to provide holes for absorbing electrons.

In an embodiment, the light emitting element is a top emission type OLED. The anode layer 401 is a non-transparent metal electrode.

In an embodiment, an orthographic projection of the anode layer 401 projected on the first protrusion 112 is located within the first protrusion 112. The anode layer 401 is electrically connected to the source drain layer 110 of the thin film transistor 200 through the first via hole 113.

A step S302 of forming a pixel defining layer 404 and a supporting layer 405 on the anode layer 401:

Refer to FIG. 3F. The pixel defining layer 404 includes a first opening 406 that is located on the anode layer 401. A sum of thicknesses of the first protrusion 112 and the anode layer 401 of the light emitting element layer 400 is smaller than a thickness of the pixel defining layer 404.

In an embodiment, material of the pixel defining layer 404 and the supporting layer 405 may be photosensitive photoresist material.

A step S303 of forming the light emitting layer 402 in the first opening 406:

Refer to FIG. 3F. The light emitting layer 402 is divided into a plurality of light emitting units by the pixel defining layer 404, and each of the light emitting units corresponds to an anode unit in the anode layer 401.

A step S304 of forming the cathode layer 403 on the light emitting layer 402:

Refer to FIG. 3G. The cathode layer 403 covers the light emitting layer 402 and the pixel defining layer 404 located on the planarization layer 111.

In an embodiment, the cathode layer 403 is transparent material.

In an embodiment, material of the cathode layer 403 may be selected from at least one of indium tin oxide (ITO), indium zinc oxide (IZO), zinc oxide (ZnO), indium oxide (In₂O₃), indium gallium oxide (IGO) or zinc aluminum oxide (AZO).

A step S40 of forming an encapsulation layer 500 on the light emitting element layer 400:

Refer to FIG. 3H. The encapsulation layer 500 may be a rigid glass cover.

In the present disclosure, vertical space between the pixel defining layer and the anode layer is reduced by adding the first protrusion on the planarization layer, thereby reducing inner shadow region generated when the light emitting layer is formed by using the metal mask, reducing the risk of pixel out of color in the display panel, and increasing the yield of the display panel.

A display module is also provided in the present disclosure. The display module includes a display panel, and includes a touch layer, a polarizing layer, and a cover layer on the display panel. The encapsulation layer is bonded to the touch layer through a first optical adhesive layer, and the polarizing layer is bonded to the cover layer through a second optical adhesive layer.

The working principle of the display module is similar to that of the display panel. For the working principle of the display module, refer to the working principle of the display panel. The details thereof are not described again herein.

A display panel, a method for manufacturing same, and a display module are provided, including a substrate, a thin film transistor layer on the substrate, a planarization layer on the thin film transistor layer, a light emitting element layer on the planarization layer; and an encapsulation layer on the light emitting element layer, wherein the planarization layer includes a first protrusion, and an orthographic projection of the light emitting element layer projected on the first protrusion is located within the first protrusion. In the present disclosure, vertical space between the pixel defining layer and the anode layer is reduced by adding the first protrusion on the planarization layer, thereby reducing inner shadow region generated when the light emitting layer is formed by using the metal mask, reducing the risk of pixel out of color in the display panel, and increasing the yield of the display panel.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

What is claimed is:

1. A display panel, comprising:
a substrate;
a thin film transistor layer disposed on the substrate;
a planarization layer disposed on the thin film transistor layer;
a light emitting element layer disposed on the planarization layer; and
an encapsulation layer disposed on the light emitting element layer;
wherein the planarization layer includes a first protrusion, and an orthographic projection of the light emitting element layer projected on the first protrusion is located within the first protrusion.

2. The display panel as claimed in claim 1, further comprising a pixel defining layer;
wherein a sum of thicknesses of the first protrusion and an anode layer of the light emitting element layer is smaller than a thickness of the pixel defining layer.

3. The display panel as claimed in claim 1, further comprising a first via hole, wherein an anode layer of the light emitting element layer is electrically connected to a source drain layer of the thin film transistor layer through the first via hole.

4. The display panel as claimed in claim 3, wherein the first via hole penetrates through the first protrusion, and penetrates through the planarization layer between the first protrusion and the source drain layer.

5. The display panel as claimed in claim 3, wherein the first via hole penetrates through the planarization layer.

6. The display panel as claimed in claim 1, wherein the planarization layer is formed by a multi-segment mask, the multi-segment mask includes a first region, a second region, and a third region, light transmittances of the first region, the second region, and the third region are sequentially increased, the first region corresponds to the first protrusion of the planarization layer, the third region corresponds to the first via hole in the planarization layer, and the second region corresponds to a region of the planarization layer other than the first protrusion and the first via hole.

7. The display panel as claimed in claim 6, wherein the light transmittances of the first region, the second region, and the third region are sequentially increased.

8. A method for manufacturing a display panel, comprising:
a step S10 of providing a substrate and forming a thin film transistor layer on the substrate;
a step S20 of forming a first film layer on the thin film transistor layer, and using a first photomask to form the first film layer into a planarization layer including a first protrusion;
a step S30 of forming a light emitting element layer on the planarization layer; and
a step S40 of forming an encapsulation layer on the light emitting element layer;
wherein an orthographic projection of the light emitting element layer projected on the first protrusion is located within the first protrusion.

9. The manufacturing method as claimed in claim 8, wherein before the step S30, the manufacturing method further comprises following steps of:
forming a pixel defining layer on the planarization layer;
wherein a sum of thicknesses of the first protrusion and an anode layer of the light emitting element layer is smaller than a thickness of the pixel defining layer.

10. The manufacturing method as claimed in claim 8, wherein the step S20 comprises:
a step S201 of forming the first film layer on the thin film transistor layer; and
a step S202 of using a multi-segment mask to pattern the first film layer into the planarization layer including the first protrusion and a first via hole;
wherein an anode layer of the light emitting element layer is electrically connected to a source drain layer of the thin film transistor layer through the first via hole.

11. The manufacturing method as claimed in claim 10, wherein the first via hole penetrates through the first protrusion, and penetrates through the planarization layer between the first protrusion and the source drain layer.

12. The manufacturing method as claimed in claim 10, wherein the multi-segment mask includes a first region, a second region, and a third region, light transmittances of the first region, the second region, and the third region are sequentially increased, the first region corresponds to the first protrusion of the planarization layer, the third region corresponds to the first via hole in the planarization layer, and the second region corresponds to a region of the planarization layer other than the first protrusion and the first via hole.

13. The manufacturing method as claimed in claim 12, wherein the light transmittances of the first region, the second region, and the third region are sequentially increased.

14. A display module including a display panel, a polarizing layer, and a cover layer on the display panel, wherein the display panel comprises:
a substrate;
a thin film transistor layer disposed on the substrate;
a planarization layer disposed on the thin film transistor layer;
a light emitting element layer disposed on the planarization layer; and
an encapsulation layer disposed on the light emitting element layer;
wherein the planarization layer includes a first protrusion, and an orthographic projection of the light emitting element layer projected on the first protrusion is located within the first protrusion.

15. The display module as claimed in claim 14, further comprising a pixel defining layer;
wherein a sum of thicknesses of the first protrusion and an anode layer of the light emitting element layer is smaller than a thickness of the pixel defining layer.

16. The display module as claimed in claim 14, further comprising a first via hole, wherein an anode layer of the light emitting element layer is electrically connected to a source drain layer of the thin film transistor layer through the first via hole.

17. The display module as claimed in claim 16, wherein the first via hole penetrates through the first protrusion, and penetrates through the planarization layer between the first protrusion and the source drain layer.

18. The display module as claimed in claim 16, wherein the first via hole penetrates through the planarization layer.

19. The display module as claimed in claim 14, wherein the planarization layer is formed by a multi-segment mask, the multi-segment mask includes a first region, a second region, and a third region, light transmittances of the first region, the second region, and the third region are sequentially increased, the first region corresponds to the first protrusion of the planarization layer, the third region corresponds to the first via hole in the planarization layer, and the second region corresponds to a region of the planarization layer other than the first protrusion and the first via hole.

20. The display module as claimed in claim 19, wherein the light transmittances of the first region, the second region, and the third region are sequentially increased.
